(19) United States
(12) Patent Application Publication
(10) Pub. No.: US 2025/0169244 A1
(43) Pub. Date: May 22, 2025

(54) SEMICONDUCTOR LIGHT-EMITTING DEVICE, METHOD OF MANUFACTURING THE SAME, AND DISPLAY APPARATUS INCLUDING THE SAME

(71) Applicant: SAMSUNG ELECTRONICS CO., LTD., Suwon-si (KR)

(72) Inventors: Joohun HAN, Suwon-si (KR); Joosung Kim, Suwon-si (KR); Junhee Choi, Suwon-si (KR); Nakhyun Kim, Suwon-si (KR); Eunsung Lee, Suwon-si (KR)

(73) Assignee: SAMSUNG ELECTRONICS CO., LTD., Suwon-si (KR)

(21) Appl. No.: 18/955,332

(22) Filed: Nov. 21, 2024

(30) Foreign Application Priority Data
Nov. 22, 2023 (KR) 10-2023-0163785

(51) Int. Cl. H01L 33/44; H01L 25/075; H01L 25/16; H01L 33/00; H01L 33/62

(52) U.S. Cl. CPC H10H 20/84; H01L 25/0753; H01L 25/167; H10H 20/01; H10H 20/857; H10H 20/034

(57) ABSTRACT

A semiconductor light-emitting device includes: a light-emitting stack structure including a first semiconductor layer, an active layer disposed on the first semiconductor layer, and a second semiconductor layer disposed on the active layer; and a first passivation layer disposed on a side surface of the light-emitting stack structure.

### CROSS-REFERENCE TO RELATED APPLICATION

This application is based on and claims priority under 35 U.S.C. § 119 to Korean Patent Application No. 10-2023-0163785, filed on Nov. 22, 2023, in the Korean Intellectual Property Office, the disclosure of which is incorporated herein in its entirety by reference.

### BACKGROUND

### 1. Field

Example embodiments consistent with the disclosure relate to a semiconductor light-emitting device with improved luminescence efficiency, a method of manufacturing the semiconductor light-emitting device, and a display apparatus including the semiconductor light-emitting device.

### 2. Description of the Related Art

Light-emitting diodes (LED) are known as a next-generation light source with a long lifespan, low power consumption, a fast response speed, environmental friendliness, etc. compared to other light sources of the related art. Thus, there are increasing industrial demands for the LEDs. LEDs may be applied to various products such as a lighting apparatus and a backlight of a display.

Recently, micro or nano-sized micro LEDs using a Group II-VI or Group III-V compound semiconductor have been developed. In addition, micro LED displays to which nanoscale LEDs are directly applied as light-emitting elements of display pixels have been developed. However, miniaturizing the LED by a micro or nano unit diminishes the luminescence efficiency of the LED.

### SUMMARY

One or more example embodiments provide a semiconductor light-emitting device with improved luminescence efficiency.

One or more example embodiments provide a method of manufacturing the semiconductor light-emitting device with improved luminescence efficiency.

One or more example embodiments provide a display apparatus including the semiconductor light-emitting device with improved luminescence efficiency.

Additional aspects will be set forth in part in the description which follows and, in part, will be apparent from the description, or may be learned by practice of the presented embodiments of the disclosure.

According to an aspect of an example embodiment of the disclosure, a semiconductor light-emitting device includes a light-emitting stack structure including a first semiconductor layer, an active layer disposed on the first semiconductor layer, and a second semiconductor layer disposed on the active layer, and a first passivation layer disposed on a side surface of the light-emitting stack structure, wherein the light-emitting stack structure is configured to emit light having a light-emitting peak wavelength in a range of about 610 nm to about 650 nm, and the first passivation layer includes aluminum oxynitride (AlON).

A composition ratio of nitrogen in AlON of the first passivation layer may be in a range of about 1 at % to about 10 at %.

A thickness of the first passivation layer may be in a range of about 1 nm to about 50 nm.

A second passivation layer may be disposed on the first passivation layer.

The second passivation layer may include at least one of SiO₂, SiN, SiCN, SiOC, SiON, SiOCN, HfOₓ, AlOₓ, ZrOₓ, AlN, AlOₓN_{y}, Ta₂O₃, or Ta₂O₅.

The second passivation layer may be stacked in one to five layers.

The second passivation layer may include an amorphous material.

A thickness of the second passivation layer may be in a range of about 1 nm to about 15 nm.

A semiconductor light-emitting device may further include a SiO₂ passivation layer and a Al₂O₃ passivation layer included in the first passivation layer.

The semiconductor light-emitting device may have a diameter in a range of about 0.5 μm to about 2 μm.

The semiconductor light-emitting device may have a height in a range of about 2 μm to about 7 μm.

According to an aspect of an example embodiment of the disclosure, a display apparatus includes a plurality of pixel electrodes, a common electrode corresponding to the plurality of pixel electrodes, a plurality of semiconductor light-emitting devices connected between each of the plurality of pixel electrodes and the common electrode, and a driving circuit layer to drive the plurality of semiconductor light-emitting devices, wherein each semiconductor light-emitting device of the plurality of semiconductor light-emitting devices includes a light-emitting stack structure including a first semiconductor layer, an active layer disposed on the first semiconductor layer, and a second semiconductor layer disposed on the active layer, and a first passivation layer disposed on a side surface of the light-emitting stack structure, wherein the light-emitting stack structure is configured to emit light having a light-emitting peak wavelength in a range of about 610 nm to about 650 nm, and wherein the first passivation layer includes aluminum oxynitride (AlON).

According to an aspect of an example embodiment of the disclosure, a method of manufacturing a semiconductor light-emitting device includes forming a first semiconductor layer on a substrate, forming an active layer on the first semiconductor layer, forming a second semiconductor layer on the active layer, forming a plurality of light-emitting stack structures by etching the first semiconductor layer, the active layer, and the second semiconductor layer, and depositing a first passivation layer on the plurality of light-emitting stack structures, wherein the plurality of light-emitting stack structures are formed to emit light having a peak wavelength in a range of about 610 nm to about 650 nm, and the depositing of the first passivation layer includes selectively repeating, a plurality of times, a process of AlN deposition and Al₂O₃ deposition and a plasma process.

The process of the AlN deposition and the Al₂O₃ deposition may include performing the AlN deposition two consecutive times and performing the Al₂O₃ deposition two consecutive times.

In the process of the AlN deposition and the Al₂O₃ deposition a plurality of times, the AlN deposition may be performed earlier than the Al₂O₃ deposition.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 schematically illustrates a semiconductor light-emitting device according to an example embodiment;

FIG. 2 is a plan view of FIG. 1;

FIG. 3 illustrates an example in which a semiconductor light-emitting device includes a second passivation layer according to an example embodiment;

FIG. 4 illustrates an example in which a semiconductor light-emitting device includes a third passivation layer according to an example embodiment;

FIG. 5 illustrates an example in which a semiconductor light-emitting device includes a superlattice layer and an electron blocking layer according to an example embodiment;

FIG. 6 illustrates an example in which a portion of a side wall of a semiconductor light-emitting device includes a first passivation layer thereon according to an example embodiment;

FIG. 7 illustrates a change in photo luminescence (PL) intensity according to wavelengths of semiconductor light-emitting devices according to example embodiments and a comparative example;

FIG. 8A to 8E are diagrams for explaining a method of manufacturing a semiconductor light-emitting device according to example embodiments;

FIG. 9 is a flowchart of a method of manufacturing a first passivation layer of a semiconductor light-emitting device according to an example embodiment;

FIG. 10 is a flowchart of a method of manufacturing a first passivation layer and a second passivation layer of a semiconductor light-emitting device according to an example embodiment;

FIGS. 11A to 11D illustrate examples of depositing an AlN layer first when manufacturing a first passivation layer of a semiconductor light-emitting device according to example embodiments;

FIGS. 12A to 12D illustrate examples of depositing a Al₂O₃ layer first when manufacturing a first passivation layer of a semiconductor light-emitting device according to example embodiments;

FIGS. 13A to 13D illustrate various examples of an atom layer deposition (ALD) method in manufacturing a first passivation layer of a semiconductor light-emitting device according to example embodiments;

FIG. 14 is a transmission election microscopy (TEM) analysis result of a semiconductor light-emitting device manufactured according to the ALD method according to FIGS. 13A to 13D;

FIG. 15 is a diagram schematically illustrating a display apparatus according to an example embodiment;

FIG. 16 illustrates an array layer of a display apparatus according to an example embodiment;

FIG. 17 is a schematic block diagram of an electronic apparatus according to an example embodiment;

FIG. 18 illustrates an example of a display apparatus, according to an example embodiment, applied to a mobile apparatus;

FIG. 19 illustrates an example of a display apparatus, according to an example embodiment, applied to a vehicle display apparatus;

FIG. 20 illustrates an example of a display apparatus, according to an example embodiment, applied to augmented reality glasses or virtual reality glasses;

FIG. 21 illustrates an example of a display apparatus, according to an example embodiment, applied to a signage; and

FIG. 22 illustrates an example of a display apparatus, according to an example embodiment, applied to a wearable display.

### DETAILED DESCRIPTION

Reference will now be made in detail to embodiments, examples of which are illustrated in the accompanying drawings, wherein like reference numerals refer to like elements throughout. In this regard, example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, with reference to the drawings, a semiconductor light-emitting device, a method of manufacturing the semiconductor light-emitting device, and a display apparatus including the semiconductor light-emitting device, according to various embodiments, will be described in detail. In the drawings, like reference numerals refer to the like elements, and sizes of elements in the drawings may be exaggerated for clarity and convenience of explanation. Terms such as “the first” and “the second” may be used to explain various elements but the elements should not be limited by terms. The terms are only used to distinguish one element from another.

The singular forms are intended to include the plural forms as well, unless the context clearly indicates otherwise. Also, it should be understood that, when a part “comprises” or “includes” an element in the specification, unless otherwise defined, other elements are not excluded from the part and the part may further include other elements. In addition, the size and thickness of each element may be exaggerated for the clarity of the description. In addition, when a predetermined material layer is described as being on a substrate or another layer, the material layer may be present on the substrate or another layer while being in direct contact with the substrate or the other layer, or another layer may be present between the material layer and the substrate of the other layer. In addition, since materials included in each layer in the embodiment below are examples, other materials may be used.

Also, in the specification, the term “units” or “ . . . modules” denote units or modules that process at least one function or operation, and may be realized by hardware, software, or a combination of hardware and software.

Particular executions described in the present embodiment are examples, and thus do not limit the technical scope in any way. For simplicity of the specification, descriptions regarding electronic elements of the prior art, control systems, software, and other functional aspects of the systems may be omitted. In addition, the connection or connection members of the lines between the elements shown in the drawing are examples of functional connection and/or physical or circuit connections, and may be replaced or be implemented as various functional connections, physical connections, or circuit connections in an actual apparatus.

The term “above” and similar directional terms may be applied to both singular and plural.

With respect to operations that constitute a method, the operations may be performed in any appropriate sequence unless the sequence of operations is clearly described or unless the context clearly indicates otherwise. In addition, the use of any and all examples, or exemplary language (e.g., “such as”) provided herein, is intended merely to better illuminate the inventive concept and does not pose a limitation on the scope of the inventive concept unless otherwise claimed.

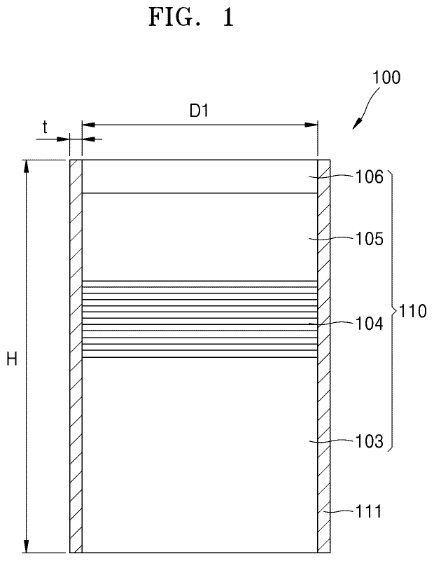

FIG. 1 illustrates a semiconductor light-emitting device 100 according to an example embodiment.

The semiconductor light-emitting device 100 may include a light-emitting stack structure 110 configured to emit light and a first passivation layer 111 disposed on a side wall (or side surface) of the light-emitting stack structure 110. The light-emitting stack structure 110 may include a first semiconductor layer 103, an active layer 104 disposed on the first semiconductor layer 103, and a second semiconductor layer 105 disposed on the active layer 104. The light-emitting stack structure 110 may further include a transparent electrode 106 disposed on the second semiconductor layer 105. In addition, although not shown, the light-emitting stack structure 110 may further include a transparent contact layer provided between the second semiconductor layer 105 and the transparent electrode 106.

The first semiconductor layer 103 and the second semiconductor layer 105 may include a Group II-VI or a Group III-V compound semiconductor material. The first semiconductor layer 103 and the second semiconductor layer 105 may provide electrons or holes to the active layer 104. To this end, the first semiconductor layer 103 may be N-doped or P-doped, and the second semiconductor layer 105 may be doped with an electrically opposite conductivity type to the first semiconductor layer 103. For example, the first semiconductor layer 103 may be N-doped and the second semiconductor layer 105 may be P-doped, or the first semiconductor layer 103 may be P-doped and the second semiconductor layer 105 may be N-doped. When the first semiconductor layer 103 or the second semiconductor layer 105 is N-doped, Si, Ge, or Sn, for example, may be used as a dopant, and when P-doped, Mg, Zn, Ca, Se, or Ba, for example, may be used as a dopant. The N-doped first semiconductor layer 103 or second semiconductor layer 105 may provide electrons to the active layer 104 and the P-doped second semiconductor layer 105 or first semiconductor layer 103 may provide holes to the active layer 104.

The first semiconductor layer 103 may include an N-type semiconductor of Group III-V, such as n-GaN. The second semiconductor layer 105 may include a P-type semiconductor of Group III-V, such as p-GaN. The first semiconductor layer 103 and the second semiconductor layer 105 may have a single layer or multilayer structure.

The active layer 104 may include a nitride semiconductor. For example, the active layer 104 may include a GaN-based material. In this case, the active layer 104 may include an undoped GaN-based material or a GaN-based material doped with certain impurities. For example, the active layer 104 may include at least one of InAlGaN, GaN, AlGaN, and InGaN. Alternatively, the active layer 104 may include at least one of AlN, InN, and AlGaInP.

The active layer 104 may have a quantum well structure in which a quantum well is provided between barriers. The electrons and holes received from the first semiconductor layer 103 and the second semiconductor layer 105 may be recombined in the quantum well in the active layer 104 to generate light. According to the energy band gap of the material included in the quantum well in the active layer 104, the wavelength of light generated in the active layer 104 may be determined. The active layer 104 may include only one quantum well or may have a multi-quantum well (MQW) structure in which a plurality of quantum wells and a plurality of barriers are alternately provided. The thickness of the active layer 104 or the number of quantum wells in the active layer 104 may be appropriately selected in consideration of a driving voltage and a luminescence efficiency of the semiconductor light-emitting device 100. If the active layer 104 has a multi-quantum well structure, for example, a quantum well structure including InGaN/GaN may be included.

For example, the light-emitting stack structure 110 may be configured to emit light of a red wavelength. The light-emitting stack structure 110 may emit, for example, light having a peak wavelength of about 610 nm to about 650 nm. The emission wavelength of the light-emitting stack structure 110 may be controlled by controlling a material composition of the active layer 104. When the active layer 104 includes In, the wavelength of light emitted from the active layer 104 may be longer when a content of In included in the active layer 104 is greater. For example, when the indium content of the active layer 104 is about 15%, the active layer 104 may emit blue light of about 450 nm; when the indium content of the active layer 104 is about 25%, the active layer 104 may emit green light of about 520 nm; and when the indium content of the active layer 104 is about 35%, the active layer 104 may release a red light of about 630 nm. However, the above description is only an example, and various configurations to emit red light are possible.

When the semiconductor light-emitting device 100 has a very small size, such as a nano size or a micro size, an external quantum efficiency (EQE) and an internal quantum efficiency (IQE) of the active layer 104 may be reduced as the emission wavelength is increased. In addition, as the indium content of the active layer 104 is increased, a defect caused by a lattice mismatch may be increased. Therefore, when the semiconductor light-emitting device 100 emits light of a red wavelength, there is a greater need to increase the luminescence efficiency of the semiconductor light-emitting device 100. The semiconductor light-emitting device 100 may, for example, control the composition of In in the material of the active layer 104 to control light emitted from the light-emitting stack structure 110 to have a wavelength of about 610 nm to about 650 nm. Alternatively, the active layer 104 may emit light of a blue wavelength and the light-emitting stack structure 110 may include a color conversion material to convert light of the blue wavelength to light of a red wavelength. For example, quantum dots may be used as a color conversion material.

The semiconductor light-emitting device 100 may have a nano rod shape having a very small size of a nano size or a micro size. However, the semiconductor light-emitting device 100 is not limited to the above and, for example, may have a microchip structure.

The semiconductor light-emitting device 100 may have a cylindrical structure. However, the shape of the semiconductor light-emitting device 100 is not limited thereto and may include various rod structures such as a square pillar, a pentagonal pillar, and a hexagonal pillar. The first semiconductor layer 103 may have a relatively great height compared to the active layer 104 or the second semiconductor layer 105. A height H of the first semiconductor layer 103 may be relatively greater than a diameter D1 of the semiconductor light-emitting device 100. For example, the diameter D1 of the semiconductor light-emitting device 100 may be about 100 μm or less. For example, the diameter D1 of the semiconductor light-emitting device 100 may be about 50 μm or less. Alternatively, the diameter D1 of the semiconductor light-emitting device 100 may be in a range of about 0.5 μm to about 2 μm. Here, the diameter D1 may have a greatest value (or in a greater range) when the diameter D1 of the semiconductor light-emitting device 100 is not uniform. The semiconductor light-emitting device 100 may generally have a uniform diameter along a height direction. However, the semiconductor light-emitting device 100 is not limited thereto.

When a length between a lower surface of the first semiconductor layer 103 and an upper surface of the second semiconductor layer 105 is the height H of the semiconductor light-emitting device 100, the height H may be in a range of about 1 μm to about 20 μm. Alternatively, the height H may be in a range of about 2 μm to about 10 μm. In addition, the semiconductor light-emitting device 100 may have, for example, a great aspect ratio of 4 or more. For example, the diameter D1 of the semiconductor light-emitting device 100 may be selected to be about 600 nm and the height H may be selected to be about 5 μm. In this case, the aspect ratio of the semiconductor light-emitting device 100 may be slightly greater than 8.

When the light-emitting stack structure 110 having a large aspect ratio is manufactured in a small size, a surface defect of the active layer 104 may be increased as a surface to volume ratio is increased. In other words, a surface defect caused by a dangling bond may be generated on an outer surface of the active layer 104, and as the surface to volume ratio is increased, an unsaturated bond is increased, and accordingly, the surface defect is increased. The surface defect may interfere with a flow of a current, thereby decreasing the luminescence efficiency of the active layer 104. As the size of the semiconductor light-emitting device 100 is decreased, luminescence efficiency of the semiconductor light-emitting device 100 is reduced, and when red light is emitted from the semiconductor light-emitting device 100, the luminescence efficiency of the semiconductor light-emitting device 100 may be further reduced.

The semiconductor light-emitting device 100 may include the first passivation layer 111 on the side wall of the light-emitting stack structure 110 to increase the luminescence efficiency of the semiconductor light-emitting device 100. The first passivation layer 111 may include aluminum oxynitride (AlON). A composition ratio of N in AlON of the first passivation layer 111 may be in a range of about 1 at % to about 10 at %. A composition ratio of O in AlON of the first passivation layer 111 may be in a range of about 58 at % to about 68 at %. A composition ratio of Al in AlON of the first passivation layer 111 may be in a range of about 30 at % to about 45 at %. The first passivation layer 111 may be in direct contact with the light-emitting stack structure 110.

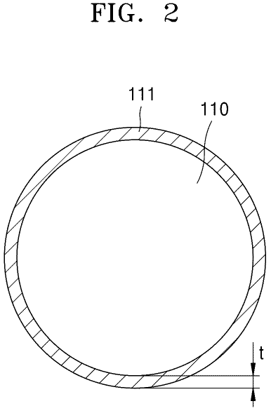

FIG. 2 is a plan view of the semiconductor light-emitting device 100 shown in FIG. 1.

The first passivation layer 111 may not only increase the luminescence efficiency of the light-emitting stack structure 110 but also protect the light-emitting stack structure 110 from external physical and/or chemical shock and prevent the leakage of current by insulating the light-emitting stack structure 110. To this end, as shown in FIG. 2, the first passivation layer 111 may completely surround the side wall of the light-emitting stack structure 110. The first passivation layer 111 may have a ring form in a planar view and may have a cylindrical shape as a whole. In FIG. 2, the light-emitting stack structure 110 is illustrated as being circular as an example, but is not necessarily limited thereto. A thickness t of the first passivation layer 111 along a diameter direction of the semiconductor light-emitting device 100, in other words, a distance between an inner side wall and an outer side wall of the first passivation layer 111 may be in a range of about 1 nm to about 50 nm. Alternatively, the thickness t of the first passivation layer 111 may have a range of about 1 nm to about 40 nm.

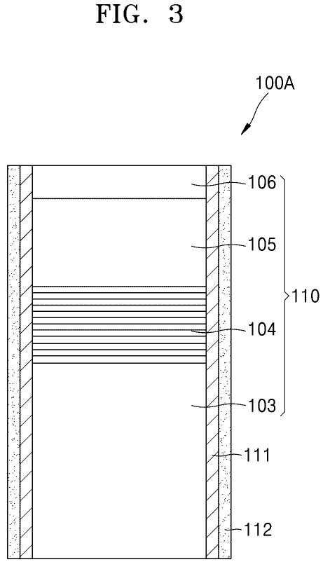

FIG. 3 illustrates an example in which a semiconductor light-emitting device 100A includes a second passivation layer 112 according to an example embodiment.

The semiconductor light-emitting device 100A may further include the second passivation layer 112 provided in the first passivation layer 111. In FIG. 3, since an element using the same reference numeral as FIG. 1 is substantially the same as the element of FIG. 1, detailed descriptions thereof are omitted. The second passivation layer 112 may include at least one of SiO₂, SiN, SiCN, SiOC, SiON, SiOCN, HfOₓ, AlOₓ, ZrOₓ, AlN, AlOₓN_{y}, Ta₂O₃, and Ta₂O₅. The second passivation layer 112 may include a single layer or multilayers. The second passivation layer 112 may include, for example, one to five layers. The thickness of the second passivation layer 112 may be in a range of about 1 nm to about 15 nm. The second passivation layer 112 may include an amorphous material. Alternatively, the second passivation layer 112 may be formed by crystal growth of a material having a crystal structure similar to that of the active layer 104. In this case, the second passivation layer 112 may have an epitaxial relationship with the active layer 104. The second passivation layer 112 may include an insulating crystal material having the same crystal structure as the crystal structure of the active layer 104. The second passivation layer 112 may have a lattice matching epitaxy relationship or a domain matching epitaxy relationship with the active layer 104. The lattice matching epitaxy relationship refers to a lattice constant of the second passivation layer 112 being almost the same as a lattice constant of the active layer 104. In addition, the domain matching epitaxial relationship indicates that the lattice constant of the second passivation layer 112 is almost the same as an integer multiple of the lattice constant of the semiconductor light-emitting device 100A or the lattice constant of the semiconductor light-emitting device 100A is almost the same as an integer multiple of the lattice constant of the second passivation layer 112. For example, the difference between a lattice constant m1 of the semiconductor light-emitting device 100A and a lattice constant m2 of the second passivation layer 112 may be within ±30% of the lattice constant m1. Thus, since the dangling bonds on the outer surface of the active layer 104 are removed, the surface defect may be prevented from being generated on the outer surface of the active layer 104. Therefore, the active layer 104 may avoid the surface defect to improve the luminescence efficiency of the semiconductor light-emitting device 100A.

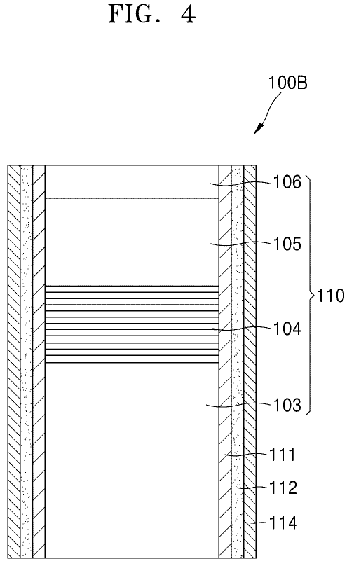

FIG. 4 illustrates an example in which a semiconductor light-emitting device 100B includes a third passivation layer 114 according to an example embodiment.

The semiconductor light-emitting device 100B may further include the third passivation layer 114 provided in the second passivation layer 112. The third passivation layer 114 may include at least one of SiO₂, SiN, SiCN, SiOC, SiON, SiOCN, HfOₓ, AlOₓ, ZrOₓ, AlN, AlOₓN_{y}, Ta₂O₃, and Ta₂O₅. For example, the second passivation layer 112 of SiO₂ and the third passivation layer 114 of Al₂O₃ may be provided on the first passivation layer 111 of AlON. Although the first passivation layer 111, the second passivation layer 112, and the third passivation layer 114 may form various combinations, a three-layer passivation layer of AlON/SiO₂/Al₂O₃ may highly improve the luminescence efficiency of the semiconductor light-emitting device 100B.

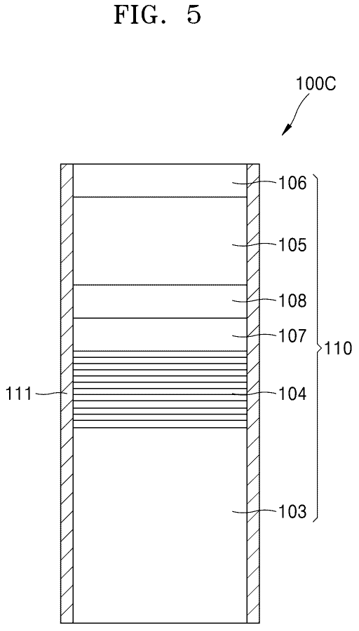

FIG. 5 illustrates an example in which a semiconductor light-emitting device 100C includes a superlattice layer and an electron blocking layer according to an example embodiment.

In the semiconductor light-emitting device 100C, a superlattice layer 107 may be provided between the second semiconductor layer 105 and the active layer 104.

The superlattice layer 107 may include, for example, an InGaN/GaN superlattice layer, an AlN/GaN superlattice layer, or an AlₓIn_{y}Ga_{(1-x-y)}N/AlₓIn_{y}Ga_{(1-x-y)}N (0≤x, y≤1, x≠y) superlattice layer. The superlattice layer 107 may relieve current spreading and strain at a lower portion of the active layer 104. The superlattice layer 107 may have a structure in which two layers are alternately laminated, for example, the InGaN/GAN superlattice layer may include an InGaN layer and a GaN layer that are alternately provided. The superlattice layer 107 may have a greater band gap than the active layer 104 so that light is not emitted from or absorbed by the superlattice layer 107. For example, the active layer 104 may include 10 pairs of layers each including layers of In₁₅Ga₇₅N/GaN deposited at thicknesses of 5 nm/5 nm and the superlattice layer 107 may include 30 pairs of layers each including layers of In₅Ga₉₅N/GaN deposited at thicknesses of 1 nm/1 nm. The In content and thickness of layers of the superlattice layer 107 may be respectively less than those of the active layer 104.

An electron blocking layer 108 may be further provided between the active layer 104 and the second semiconductor layer 105. The electron blocking layer 108 may include AlGaN, AlInN, or AlInGaN. The electron blocking layer 108 may have a thickness of 3 nm or more. The electron blocking layer 108 may prevent electron tunneling to efficiently prevent electron leakage.

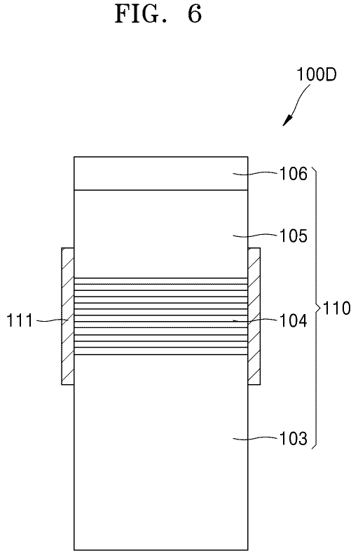

The semiconductor light-emitting device 100, 100A, 100B, 100C, or 100D (refer to FIG. 6) according to an example embodiment may include the first passivation layer 111 including AlON to improve the luminescence efficiency of red light having a peak wavelength of about 610 nm to about 650 nm.

FIG. 6 illustrates an example in which a location of the first passivation layer 111 is changed in a semiconductor light-emitting device 100D according to an example embodiment. In the above example embodiments, it is illustrated that the first passivation layer 111 entirely covers side walls of the first semiconductor layer 103, the active layer 104, and the second semiconductor layer 105. However, embodiments are not limited thereto. Referring to FIG. 6, in the semiconductor light-emitting device 100D, the first passivation layer 111 may cover only a portion of the side wall of the light-emitting stack structure 110. The first passivation layer 111 may cover only the active layer 104 or only a portion of the side wall of the light-emitting stack structure 110 including at least the active layer 104.

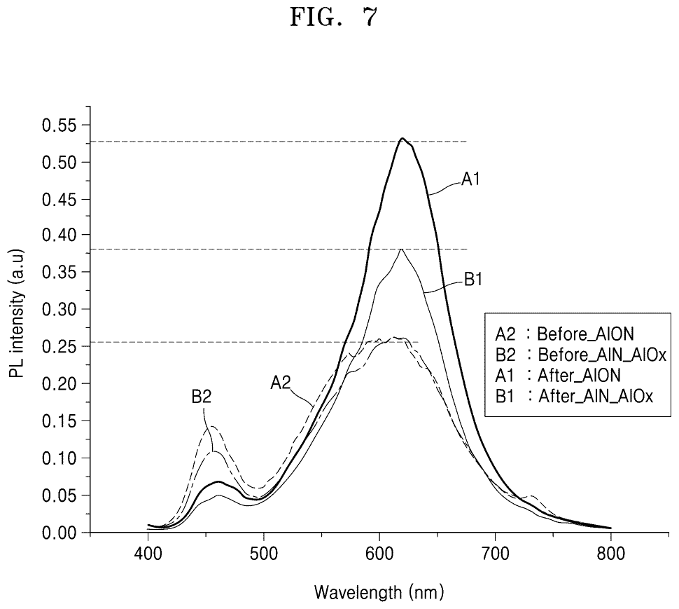

FIG. 7 illustrates a change in photo luminescence (PL) intensity according to wavelengths of the semiconductor light-emitting devices according to example embodiments and a comparative example.

A graph A1 represents a case in which the semiconductor light-emitting device includes the first passivation layer of AlON, and a graph A2 represents a case in which the semiconductor light-emitting device does not include the passivation layer of AlON. The graph A1 shows a relatively high PL intensity in a peak wavelength of 620 nm compared with the graph A2. As a comparative example, a graph B1 represents a case in which the AlN passivation layer and an AlOx passivation layer are included, and a graph B2 represents a case in which these passivation layers are not included. The graph A1 shows a relatively higher PL intensity in a peak wavelength of 620 nm compared with the graph B1.

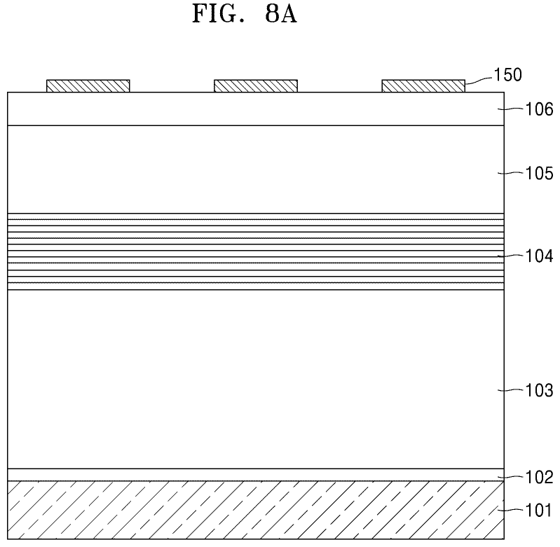

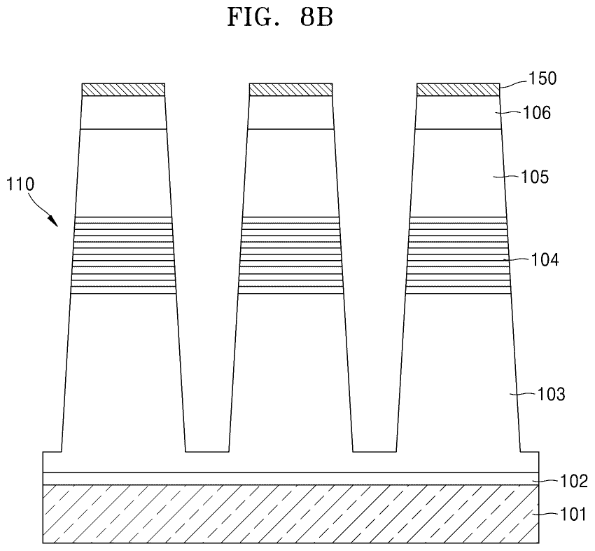

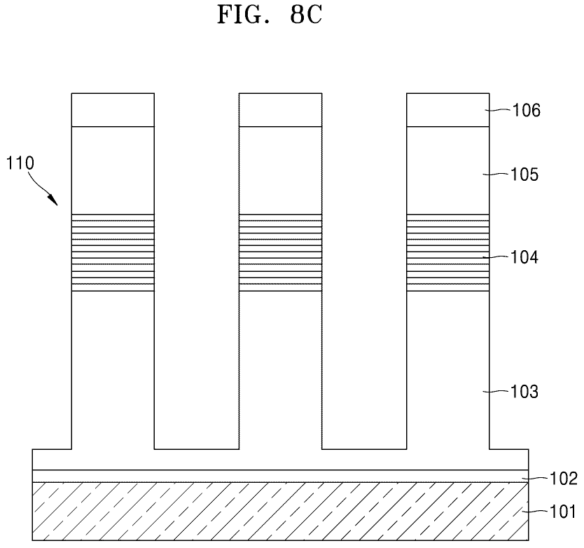

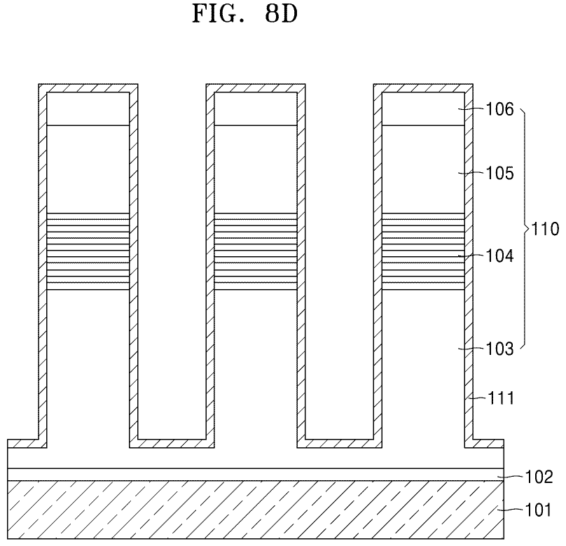

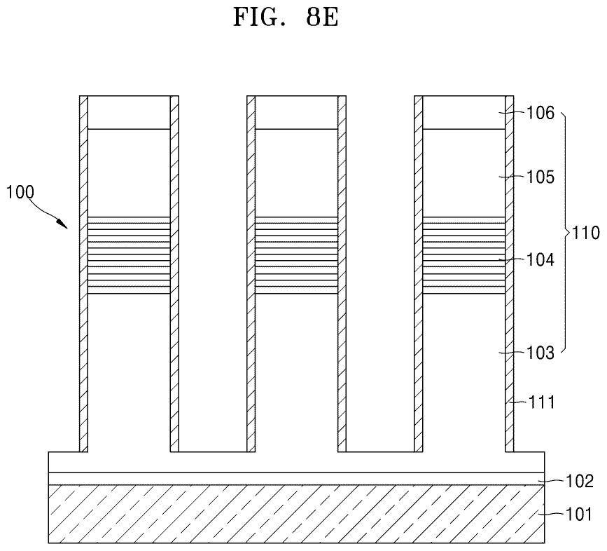

Hereinafter, with reference to FIGS. 8A to 13D, a method of manufacturing the semiconductor light-emitting device according to example embodiments will be described.

Referring to FIG. 8A, the first semiconductor layer 103, the active layer 104, and the second semiconductor layer 105 may be formed on the substrate 101. The first semiconductor layer 103 may be an N-type semiconductor layer and may include, for example, an N-type GaN. The active layer 146 may have a quantum well structure or a multi-quantum well structure. The active layer 104 may include at least one of InAlGaN, GaN, AlGaN, and InGaN. Alternatively, the active layer 104 may include at least one of AlN, InN, and AlGaInP. The active layer 104 may be configured to emit light having a peak wavelength of 610 nm to 650 nm.

The second semiconductor layer 105 may be a P-type semiconductor layer and may include, for example, a P-type GaN. A buffer layer 102 may be formed between the substrate 101 and the first semiconductor layer 103.

The substrate 101 and the buffer layer 102 may include a Group II-VI or a Group III-V compound semiconductor material. Alternatively, the substrate 101 may include a silicon substrate. The substrate 101 and the buffer layer 102 may be doped with the same conductive type as the first semiconductor layer 103. For example, when the first semiconductor layer 103 is N-doped, the substrate 101 and the buffer layer 102 may include n-GaAs. The substrate 101 may be doped at a lower concentration than the buffer layer 102, and the buffer layer 102 may be doped at a higher concentration than the substrate 101. Although not shown in FIG. 8A, a contact layer for an ohmic contact may be provided between the buffer layer 102 and the first semiconductor layer 103. The contact layer provided between the buffer layer 102 and the first semiconductor layer 103 may be doped with the same conductive type as the first semiconductor layer 103, and may be doped at a higher concentration than the doping concentration of the buffer layer 102 and the first semiconductor layer 103.

The transparent electrode 106 may be further formed on the second semiconductor layer 105. In addition, the contact layer may also be provided between the second semiconductor layer 105 and the transparent electrode 106. For example, the contact layer may include GaInP or GaAs, or may include both GaInP and GaAs. The contact layer may provide an ohmic contact. The contact layer may be doped with the same conductive type as that of the second semiconductor layer 105. For example, when the second semiconductor layer 105 is P-doped, the contact layer may also be P-doped.

The active layer 104 may include at least one of InAlGaN, GaN, AlGaN, and InGaN. Alternatively, the active layer 104 may include at least one of AlN, InN, and AlGaInP. The composition ratio of the active layer 104 may be controlled to generate red light having a peak wavelength of 610 nm to 650 nm. For example, the active layer 104 may include AlGaInP. AlGaInP of the active layer 104 may not be doped. The active layer 104 may include a barrier and a quantum well, in which the content of Al in AlGaInP may change. For example, the Al content is higher in the barrier than in the quantum well. In addition, compared to the first and second semiconductor layers 103 and 105, the content of Al is the greatest in the first and second semiconductor layers 103 and 105, the content of Al in the barrier in the active layer 104 is the second greatest, and the content of Al is the least in quantum well in the active layer 104. Then, in a conduction band, the energy level of the first and second semiconductor layers 103 and 105 is the highest, and the energy level of the barrier in the active layer 104 is the second highest, and the energy level of the quantum water in the active layer 104 is the lowest. Even if other semiconductor materials are used in addition to AlGaInP, the active layer 104 may be formed to include a barrier and a quantum well by adjusting the composition of the material.

After forming the transparent electrode 106, a hard mask 150 including a plurality of openings disposed at regular intervals may be formed on the transparent electrode 106. For example, after a material of the hard mask 150 is formed on the entire upper surface of the transparent electrode 106, the hard mask 150 may be formed by using a lithography method in which the material of the hard mask 150 is patterned to have a plurality of openings at regular intervals. The hard mask 150 may be formed, for example, as a SiO₂ single layer or a SiO₂/Al double layer. Although not shown in the cross-sectional view of FIG. 8A, the hard mask 150 as viewed from above (or in a plan view) may have a plurality of two-dimensionally disposed openings.

Referring to FIG. 8B, regions that are not covered with the hard mask 150 may be eliminated by etching through a dry etching method. For example, by sequentially etching and removing the transparent electrode 106, the second semiconductor layer 105, the active layer 104, and the first semiconductor layer 103 under the opening of the hard mask 150, the transparent electrode 106, the second semiconductor layer 105, the active layer 104, and the first semiconductor layer 103 may be patterned in the form of a plurality of nano rods. Accordingly, as shown in FIG. 8B, a plurality of light-emitting stack structures 110 each including the transparent electrode 106, the second semiconductor layer 105, the active layer 104, and the first semiconductor layer 103 may be formed at once on the substrate 101 and the buffer layer 102. In FIG. 8B, although it is shown that a lower region of the first semiconductor layer 103 remains partially, embodiments are not limited thereto and etching may be performed until the buffer layer 102 is exposed. Then, the lower region of the first semiconductor layer 103 may be completely etched and the buffer layer 102 may remain entirely or partially.

The light-emitting stack structures 110 formed in FIG. 8B may have a diameter gradually decreasing in the height direction from the first semiconductor layer 103 to the transparent electrode 106. Referring to FIG. 8C, for example, through wet etching using a KOH solution, the diameter of the light-emitting stack structures 110 may become uniform in the height direction. In this process, the hard mask 150 may also be removed.

Referring to FIG. 8D, the first passivation layer 111 may be evenly formed on the surface of the light-emitting stack structure 110. To form the first passivation layer 111, for example, after depositing a passivation layer material several times using an atomic layer deposition (ALD) method, heating and crystalizing the deposited passivation layer material may be repeated. The process of forming the first passivation layer 111 will be described later.

Referring to FIG. 8E, the first passivation layer 111 provided between adjacent light-emitting stack structures 110 and the first passivation layer 111 on the upper surface of the light-emitting stack structure 110 may be removed. Then, only the first passivation layer 111 surrounding the side wall of the plurality of light-emitting stack structures 110 may remain. Through the above method, a plurality of semiconductor light-emitting devices 100 may be formed at once on the substrate 101 and the buffer layer 102. Then, by removing the buffer layer 102, the plurality of semiconductor light-emitting device 100 may be separated individually. Alternatively, the substrate 101 and the buffer layer 102 may be cut in a vertical direction and each of the semiconductor light-emitting devices 100 may be used in a state in which the substrate 101 and the buffer layer 102 are attached together on the semiconductor light-emitting device 100. Alternatively, the substrate 101 and the buffer layer 102 may be cut in the vertical direction such that two or more semiconductor light-emitting devices 100 remain, so as to use the two or more semiconductor light-emitting devices 100 together.

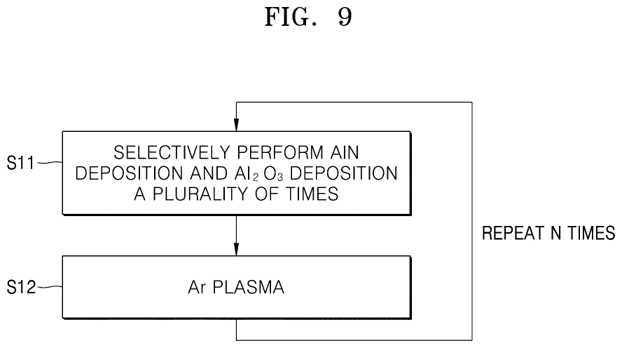

FIG. 9 is a flowchart illustrating a process of forming the first passivation layer 111 according to an example embodiment. Referring to FIG. 9, depositing the first passivation layer 111 material may be repeated several times by using the ALD method. When depositing the first passivation layer, AlN deposition and Al₂O₃ deposition may be optionally performed a plurality of times (S11). For example, AlN deposition-Al₂O₃ deposition-AlN deposition-Al₂O₃ deposition may be performed or AlN deposition-AlN deposition-Al₂O₃ deposition-Al₂O₃ deposition may be performed. In addition, it is possible to deposit the first passivation layer 111 through various combinations of AlN deposition and Al₂O₃ deposition. Although the thickness of the passivation layer material may vary depending on the passivation layer material, the thickness of the deposited passivation layer material may be increased by about 0.5 nm per deposition. Then, the deposited passivation layer material may be heated through a plasma process (S12). For example, the deposited passivation layer material may be crystalized using an argon (Ar) plasma method.

For example, the plasma process may be performed for about 40 seconds at 450 W. In addition, until the thickness of the first passivation layer 111 reaches a target thickness, depositing the first passivation layer material S11 and the plasma process S12 may be repeated n times, for example, 1 to 40 times. Alternatively, n may include a range of 1 to 30 times. Through this process, the first passivation layer 111 including AlON may be formed.

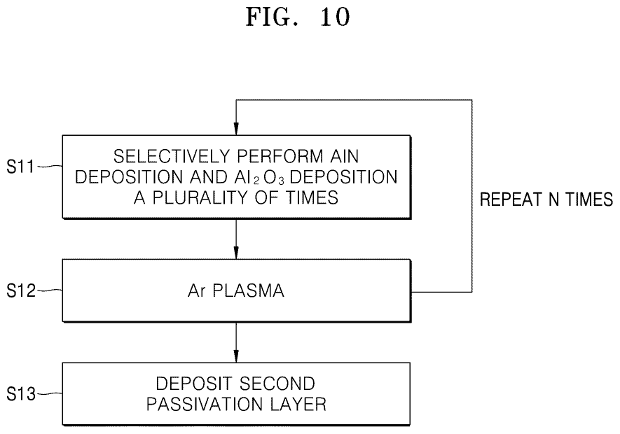

FIG. 10 shows a flow chart including a process of further depositing the second passivation layer 112 on the first passivation layer 111 according to an example embodiment. After repeating the process of depositing the first passivation layer material (S11) and the plasma process (S12) n times, the second passivation layer 112 may be deposited on the first passivation layer material 111 (S13). The second passivation layer 112 may include at least one of SiO₂, SiN, SiCN, SiOC, SiON, SiOCN, HfOₓ, AlOₓ, ZrOₓ, AlN, AlOₓN_{y}, Ta₂O₃, and Ta₂O₅. The second passivation layer 112 may be formed, for example, by depositing the second passivation layer material several times by using the ALD method. The second passivation layer 112 may include an amorphous material.

According to this method, it is possible to form the first passivation layer 111 surrounding the surface of the light-emitting stack structure 110 while minimizing the damage of the light-emitting stack structure 110. In the process of depositing the first passivation layer S11, the number of deposition may be determined in consideration of the thickness of the passivation layer material that allows the performance of the Ar plasma process without damaging the light-emitting stack structure 110.

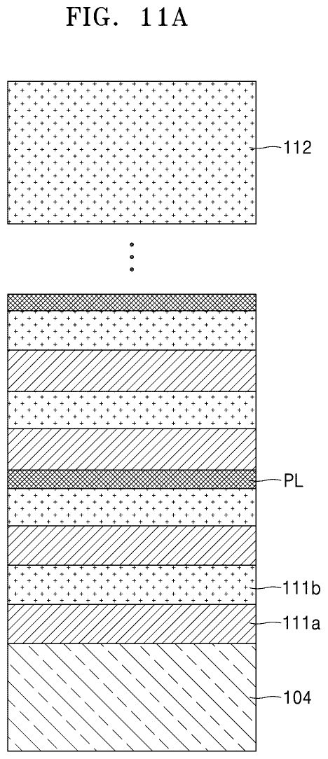

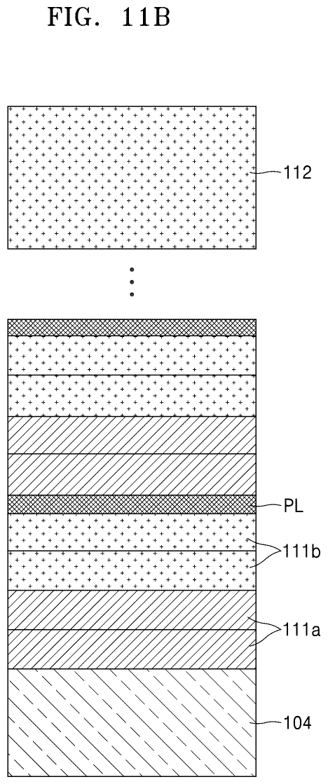

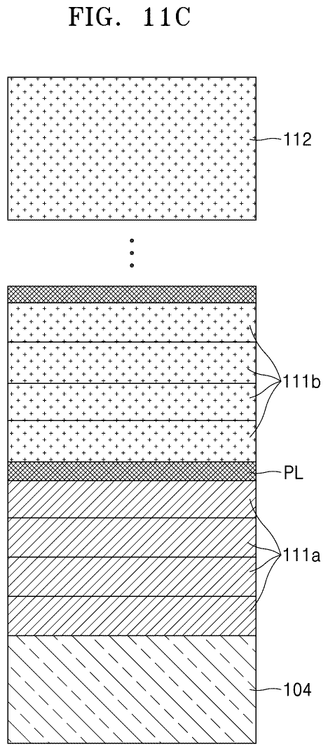

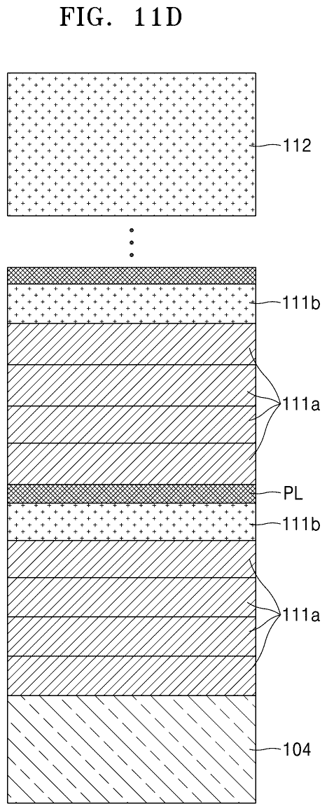

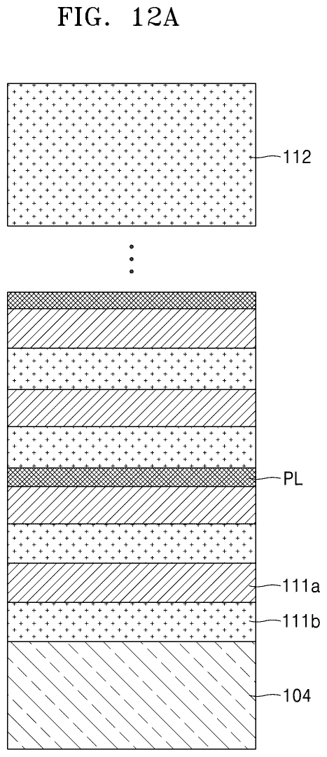

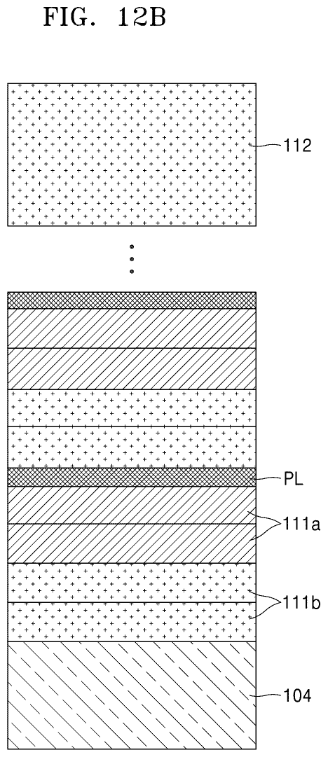

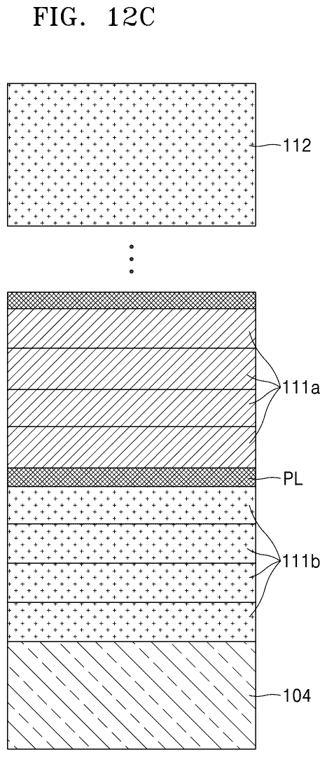

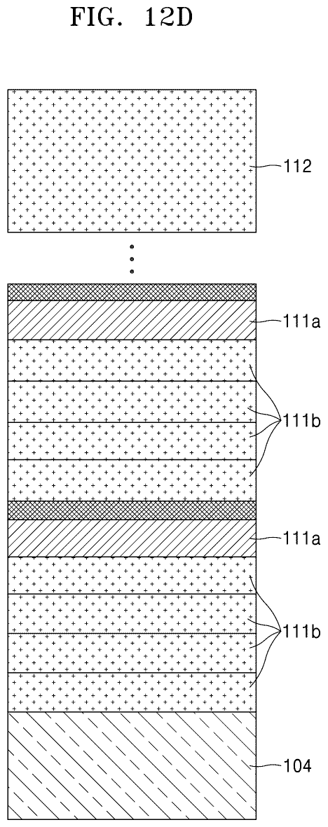

FIGS. 11A to 12D illustrate examples of the process of depositing the first passivation layer 111 according to example embodiments. FIGS. 11A to 11D illustrate an example of a process of depositing AlN earlier than Al₂O₃ when depositing the first passivation layer 111, and FIGS. 12A to 12D illustrate an example of a process of depositing Al₂O₃ earlier than AlN when depositing the first passivation layer 111. In the drawing, for convenience of illustration, it is described that the first passivation layer 111 is deposited on the active layer 104.

Referring to FIG. 11A, AlN layer 111a/Al₂O₃ layer 111b/AlN layer 111a/Al₂O₃ layer 111b may be sequentially deposited on the active layer 104, and then the plasma (PL) process may be performed. The above process may be repeated selectively, for example, within a range of 2-40 times. However, the number is merely an example. Therefore, the first passivation layer 111 of AlON may be formed. Then, the second passivation layer 112 may be deposited.

Referring to FIG. 11B, AlN layer 111a/AlN layer 111a/Al₂O₃ layer 111b/Al₂O₃ layer 111b may be sequentially deposited on the active layer 104, and then the PL process may be performed. The above process may be repeated selectively, for example, within a range of 2-40 times. Then, the second passivation layer 112 may be deposited.

Referring to FIG. 11C, AlN layer 111a/AlN layer 111a/AlN layer 111a/AlN layer 111a may be sequentially deposited on the active layer 104, and then the PL process may be performed. In addition, Al₂O₃ layer 111b/Al₂O₃ layer 111b/Al₂O₃ layer 111b/Al₂O₃ layer 111b may be sequentially deposited, and then the PL process may be performed. The above process may be repeated selectively within a range of 2-40 times. Then, the second passivation layer 112 may be deposited.

Referring to FIG. 11D, AlN layer 111a/AlN layer 111a/AlN layer 111a/AlN layer 111a/Al₂O₃ layer 111b may be sequentially deposited on the active layer 104, and then the PL process may be performed. The above process may be repeated selectively within a range of 2-40 times. Then, the second passivation layer 112 may be deposited.

Referring to FIG. 12A, Al₂O₃ layer 111b/AlN layer 111a/Al₂O₃ layer 111b/AlN layer 111a may be sequentially deposited on the active layer 104, and then the PL process may be performed. The above process may be repeated selectively, for example, within a range of 2-40 times. However, the number is merely an example. Therefore, the first passivation layer 111 of AlON may be formed. Then, the second passivation layer 112 may be deposited.

Referring to FIG. 12B, Al₂O₃ layer 111b/Al₂O₃ layer 111b/AlN layer 111a/AlN layer 111a may be sequentially deposited on the active layer 104, and then the PL process may be performed. The above process may be repeated selectively, for example, within a range of 2-40 times. Then, the second passivation layer 112 may be deposited.

Referring to FIG. 12C, Al₂O₃ layer 111b/Al₂O₃ layer 111b/Al₂O₃ layer 111b/Al₂O₃ layer 111b may be sequentially deposited on the active layer 104, and then the PL process may be performed. In addition, AlN layer 111a/AlN layer 111a/AlN layer 111a/AlN layer 111a may be sequentially deposited, and then the PL process may be performed. The above process may be repeated selectively within a range of 2-40 times. Then, the second passivation layer 112 may be deposited.

Referring to FIG. 12D, Al₂O₃ layer 111b/Al₂O₃ layer 111b/Al₂O₃ layer 111b/Al₂O₃ layer 111b/AlN layer 111a may be sequentially deposited on the active layer 104, and then the PL process may be performed. The above process may be repeated selectively within a range of 2-40 times. Then, the second passivation layer 112 may be deposited.

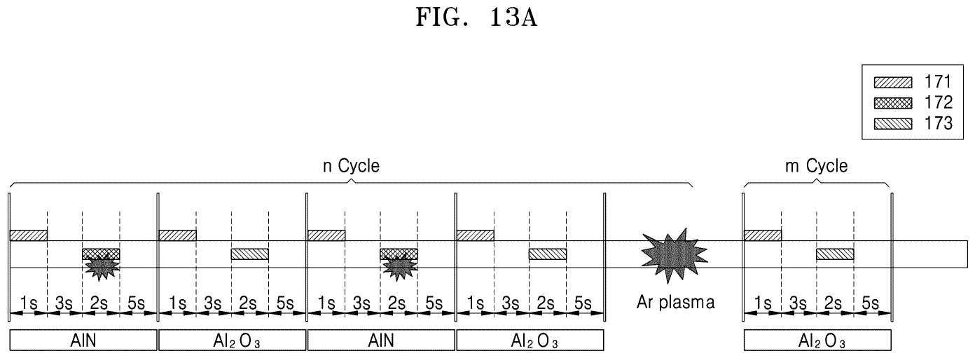

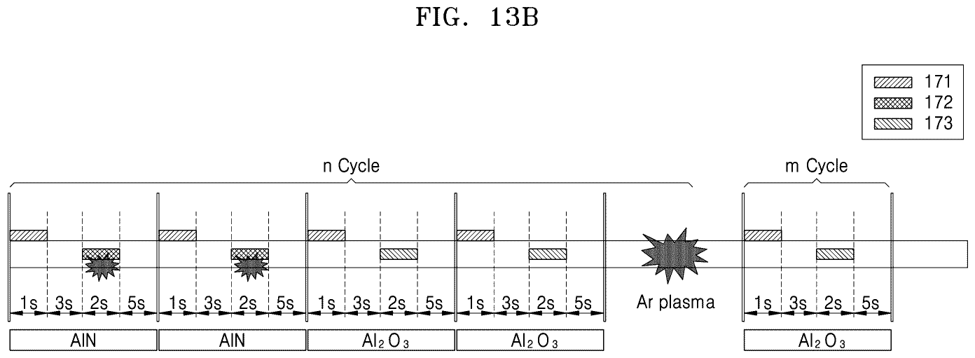

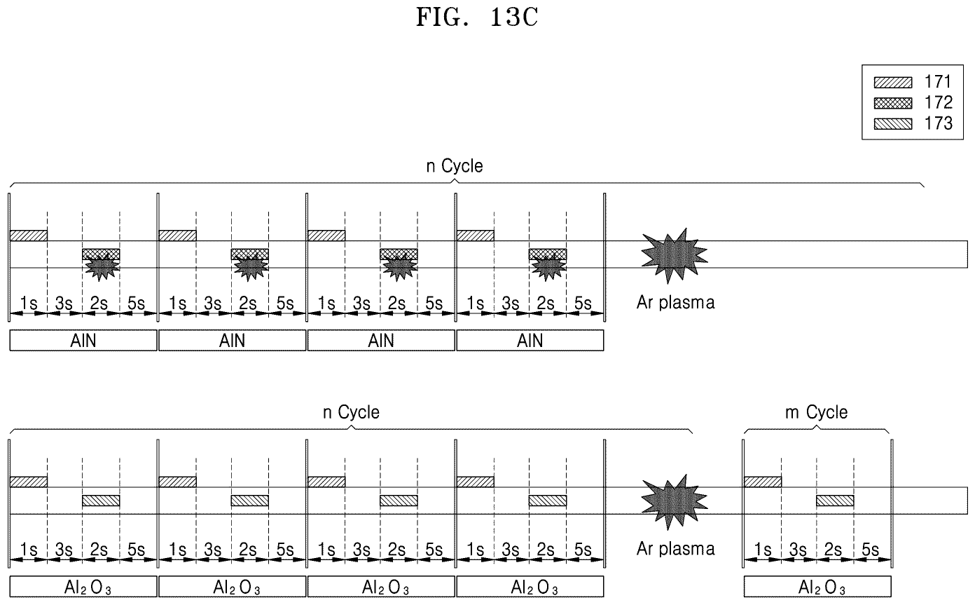

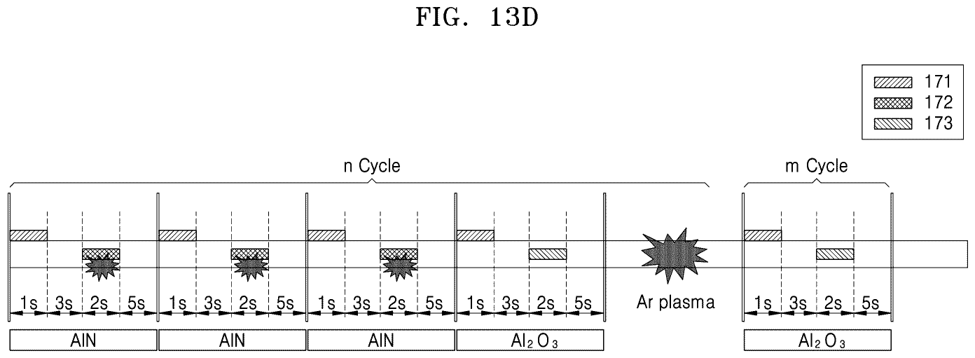

FIGS. 13A to 13D illustrates the manufacturing process of FIGS. 11A to 11D in more detail.

FIG. 13A illustrates the depositing method of FIG. 11A. Referring to FIG. 13A, AlN deposition may include injecting a tri-methyl aluminum (TMA) precursor 171 in the chamber, purging, injecting a NH₃ reactant 172 into a chamber to react with the TMA precursor 171, and purging. Purging may include flowing Ar or N₂ gas into a chamber to remove additional precursors and reaction by-products inside the chamber. A plasma process may be performed in supplying the NH₃ reactant 172. AlN deposition may be performed by a plasma enhanced (PE) atomic layer deposition method.

Al₂O₃ deposition may include injecting the TMA precursor 171 into the chamber, purging, injecting an ozone reactant 173 into the chamber to react with the TMA precursor 171, and purging. The Al₂O₃ deposition may be performed by a thermal ALD method. According to the above method, AlN deposition/Al₂O₃ deposition/AlN deposition/Al₂O₃ deposition may be performed, and then an Ar plasma process may be performed. The above five steps form a cycle, and the cycle may be performed n (n is a natural number) times, for example, 25 cycles may be performed. The first passivation layer 111 deposited in the above manner may have a thickness in a range of 1 nm to 50 nm. The composition ratio of N in AlON of the first passivation layer 111 may be in a range of 1 at % to 10 at %. The composition ratio of O in AlON of the first passivation layer 111 may be in a range of 58 at % to 68 at %. The composition ratio of Al in AlON of the first passivation layer 111 may be in a range of 30 at % to 45 at %.

As described above, the first passivation layer 111 may be deposited through n cycles. Then, the second passivation layer 112 may be deposited. The second passivation layer 112 may be formed by an Al₂O₃ ALD process. The ALD process of the second passivation layer 112 may include injecting the TMA precursor 171 in the chamber, purging, injecting an ozone reactant 173 into a chamber to react with the TMA precursor 171, and purging. The above cycle may be performed m (m is a natural number) times, for example, 405 cycles may be performed. The thickness of the second passivation layer 112 may be in a range of 1 nm to 15 nm.

FIG. 13B illustrates the depositing method of FIG. 11B. Referring to FIG. 13B, in the deposition of the first passivation layer 111, AlN deposition/AlN deposition/Al₂O₃ deposition/Al₂O₃ deposition/plasma process form a cycle. AlN deposition and Al₂O₃ deposition are described with reference to FIG. 13A. For example, the above cycle may be performed n (n is a natural number) times, for example, 25 cycles may be performed.

FIG. 13C illustrates the depositing method of FIG. 11C. Referring to FIG. 13C, in the deposition of the first passivation layer 111, AlN deposition/AlN deposition/AlN deposition/AlN deposition/plasma process/Al₂O₃ deposition/Al₂O₃ deposition/Al₂O₃ deposition/Al₂O₃ deposition/plasma process form a cycle. AlN deposition and Al₂O₃ deposition are described with reference to FIG. 13A. For example, the above cycle may be performed n (n is a natural number) times, for example, 12 cycles may be performed.

FIG. 13D illustrates the depositing method of FIG. 11D. Referring to FIG. 13D, in the deposition of the first passivation layer 111, AlN deposition/AlN deposition/AlN deposition/Al₂O₃ deposition/plasma process forms a cycle. AlN deposition and Al₂O₃ deposition are described with reference to FIG. 13A. For example, the above cycle may be performed n (n is a natural number) times, for example, 20 cycles.

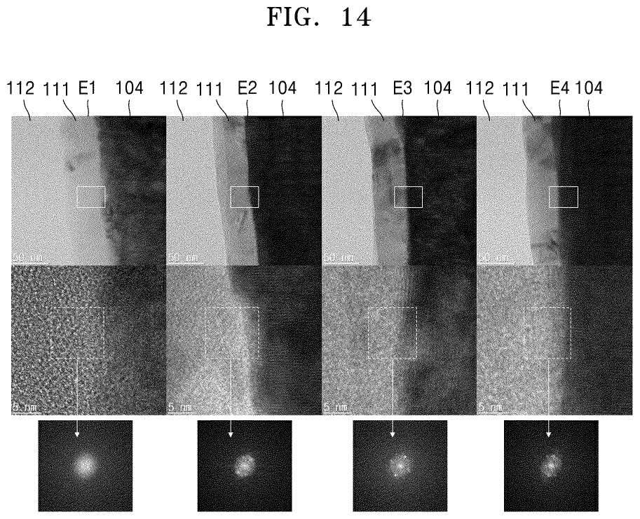

FIG. 14 illustrates results of transmission election microscopy (TEM) analysis of the semiconductor light-emitting devices prepared according to the method illustrated in FIGS. 13A to 13D. E1, E2, E3, and E4 respectively show the semiconductor light-emitting devices manufactured according to the methods illustrated in FIGS. 13A to 13D, respectively. The first passivation layer 111 including AlON may be confirmed.

As described above, in the method of manufacturing the semiconductor light-emitting device according to an example embodiment, the first passivation layer including AlON may be manufactured using the ALD process. When AlN is deposited earlier than Al₂O₃ in the manufacturing the AlON passivation layer, the PL intensity of the semiconductor light-emitting device may be relatively increased compared to when Al₂O₃ is deposited earlier than AlN. However, even if Al₂O₃ is deposited earlier than AlN, the PL intensity of the semiconductor light-emitting device may be increased compared to the related semiconductor light-emitting device. In addition, sequentially depositing AlN/AlN/Al₂O₃/Al₂O₃ may relatively increase the PL strength of the semiconductor light-emitting device compared to other cases.

As described above, the semiconductor light-emitting device(s) according to one or more example embodiments may emit red light having a peak wavelength of 610 nm to 650 nm, and the luminescence efficiency may be increased by including the first passivation layer 111. Using the above characteristics, the semiconductor light-emitting device according to one or more example embodiments may be applied to various electronic apparatuses.

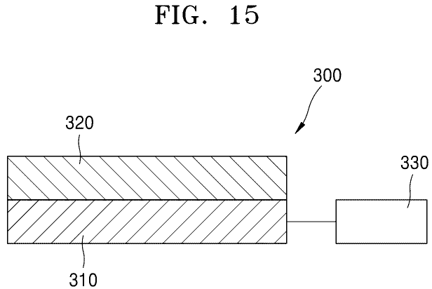

FIG. 15 is a diagram schematically illustrating a display apparatus 300 according to an example embodiment. The display apparatus 300 may include a display substrate 310 including a driving circuit, an array layer 320 disposed on the display substrate 310, and a controller 330 to input an image signal into the display substrate 310. The driving circuit may include at least one transistor and at least one capacitor. A plurality of semiconductor light-emitting devices may be disposed on the array layer 320.

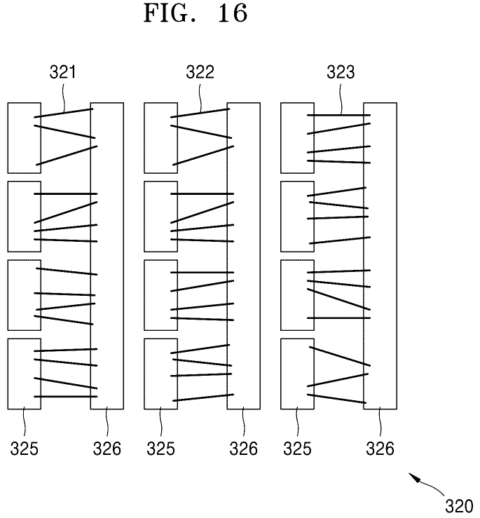

FIG. 16 illustrates an array layer according to an example embodiment.

A first semiconductor light-emitting device 321, a second semiconductor light-emitting device 322, and a third semiconductor light-emitting device 323 may be included in the array layer 320 and may be used as light-emitting elements of pixels of next-generation display apparatuses. For example, the first semiconductor light-emitting device 321 may emit blue light, the second semiconductor light-emitting device 322 may emit green light, and the third semiconductor light-emitting device 323 may emit red light. Here, the semiconductor light-emitting devices 100, 100A, 100B, 100C, and 100D described with reference to FIGS. 1 to 6 may be applied to the third semiconductor light-emitting device 323. The array layer 320 may include a plurality of pixel electrodes 325, a common electrode 326 corresponding to the plurality of pixel electrodes 325, a plurality of first semiconductor light-emitting devices 321 connected between each of the pixel electrodes 325 and the common electrode 326, a plurality of second semiconductor light-emitting devices 322 connected between each of the pixel electrodes 325 and the common electrode 326, and a plurality of third semiconductor light-emitting devices 323 connected between each of the pixel electrodes 325 and the common electrode 326.

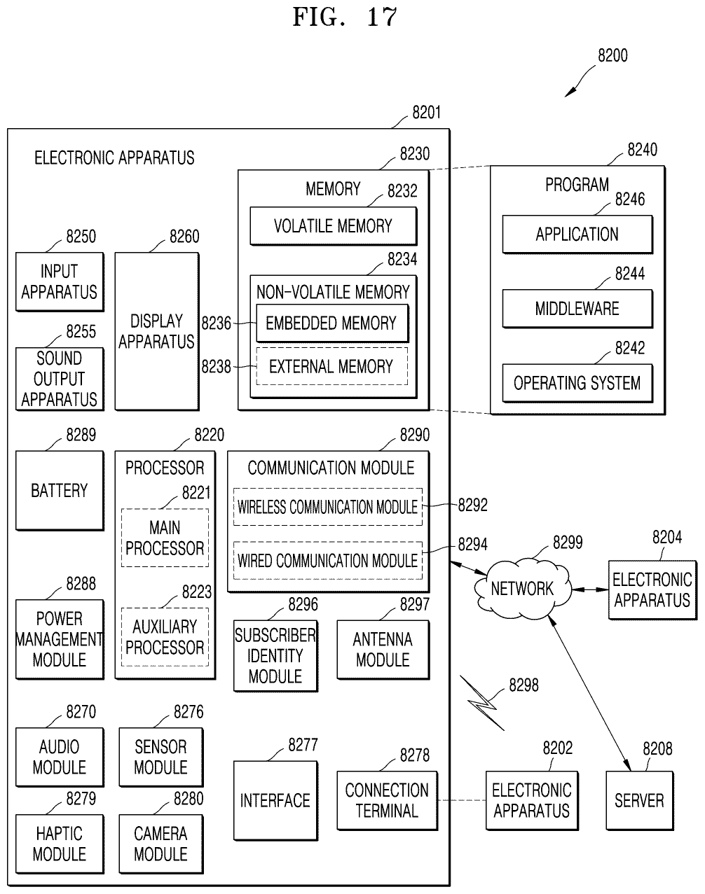

FIG. 17 illustrates a block diagram of an electronic apparatus including a display apparatus according to an example embodiment.

Referring to FIG. 17, an electronic apparatus 8201 may be provided in a network environment 8200. In a network environment 8200, the electronic apparatus 8201 may communicate with another electronic apparatus 8202 through a first network 8298 (e.g., a short-range wireless communication network), or may communicate with another electronic apparatus 8204 and/or a server 8208 through a second network 8299 (a long-range wireless communication network. The electronic apparatus 8201 may communicate with the electronic apparatus 8204 through the server 8208. The electronic apparatus 8201 may include a processor 8220, memory 8230, an input apparatus 8250, a sound output apparatus 8255, an audio module 8270, a sensor module 8276, an interface 8277, a haptic module 8279, the camera module 8280, a power management module 8288, a battery 8289, a communication module 8290, the subscriber identification module 8296, and/or an antenna module 8297. In the electronic apparatus 8201, some of the above elements may be omitted or other components may be added. Some of the elements may be implemented as an integrated circuit. For example, the sensor module 8276 (e.g., a fingerprint sensor, an iris sensor, an illuminance sensor, etc.) may be embedded in the display apparatus 8260 (e.g., a display, etc.).

The processor 8220 may execute software (e.g., a program 8240, etc.) to control another element or a plurality of other elements (e.g., hardware, software components, etc.) of the electronic apparatus 8201 connected to the processor 8220 and may perform processing or operation of various data. As part of the data processing or operation, the processor 8220 may load commands and/or data received from other components (e.g., the sensor module 8276, the communication module 8290, etc.) onto the volatile memory 8232, process the commands and/or data stored in the volatile memory 8232, and store result data on the non-volatile memory 8234. The non-volatile memory 8234 may include an embedded memory 8236 and an external memory 8238. The processor 8220 may include a main processor 8221 (e.g., a central processing apparatus, an application processor, etc.) and an auxiliary processor 8223 (e.g., a graphic processing apparatus, an image signal processor, a sensor hub processor, a communication processor, etc.) that may be operated independently from or together with the main processor 8221. The auxiliary processor 8223 may use less power than the main processor 8221 and perform specialized functions.

When the main processor 8221 is in an inactive state (a sleep state) or in an active state (an application execution state), the auxiliary processor 8223 may, either in place of or together with the main processor 8221, control functions and/or states of some components (e.g., the display apparatus 8260, the sensor module 8276, the communication module 8290, etc.) of the components of the electronic apparatus 8201. The auxiliary processor 8223 (e.g., an image signal processor, a communication processor, etc.) may be implemented as a portion of other components (e.g., the camera module 8280, the communication module 8290, etc.) that are technically related to the auxiliary processor 8223.

The memory 8230 may store various data required by the components (e.g., the processor 8220, the sensor module 8276, etc.) of the electronic apparatus 8201. Data may include, for example, software (e.g., the program 8240, etc.) and input data and/or output data of commands related to the software. The memory 8230 may include the volatile memory 8232 and/or the non-volatile memory 8234.

The program 8240 may be stored as a software in the memory 8230 and may include an operating system 8242, middleware 8244, and/or an application 8246.

The input apparatus 8250 may receive, from the outside (e.g., the user, etc.) of the electronic apparatus 8201, commands and/or data to be used in the components (e.g., the processor 8220, etc.) of the electronic apparatus 8201. The input apparatus 8250 may include a remote controller, a microphone, a mouse, a keyboard, and/or a digital pen (e.g., a stylus pen, etc.).

The sound output apparatus 8255 may output a sound signal to the outside of the electronic apparatus 8201. The sound output apparatus 8255 may include a speaker and/or a receiver. The speaker may be used for general purposes, such as playing multimedia or playing record, and the receiver may be used for receiving incoming calls. The receiver may be implemented as part of or separate from the speaker.

The display apparatus 8260 may visually provide information to the outside of the electronic apparatus 8201. The display apparatus 8260 may include a display, a hologram apparatus, or a projector and control circuitry to control a corresponding one of the display, the hologram apparatus, and the projector. The display apparatus 8260 may include a display apparatus according to an example embodiment. The display apparatus 8260 may include touch circuitry adapted to detect a touch and/or sensor circuitry (e.g., a pressure sensor, etc.) adapted to measure the intensity of force incurred by the touch.

The audio module 8270 may convert sound to an electrical signal or convert the electrical signal to sound. The audio module 8270 may obtain the sound via the input apparatus 8250, or output the sound via the sound output apparatus 8255 and/or a speaker and/or headphone of another electronic apparatus (e.g., the electronic apparatus 8202, etc.) directly or wirelessly connected to the electronic apparatus 8201.

The sensor module 8276 may detect an operational state (e.g., power, temperature, etc.) of the electronic apparatus 8201 or an external environmental state (e.g., a state of a user, etc.), and then generate an electrical signal and/or data value corresponding to the detected state. The sensor module 8276 may include a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 8277 may support one or more specified protocols to be used to directly or wirelessly connect the electronic apparatus 8201 with another electronic apparatus (e.g., the electronic apparatus 8202, etc.). The interface 8277 may include a high definition multimedia interface (HDMI), a universal serial bus (USB) interface, a secure digital (SD) card interface, and/or an audio interface.

A connecting terminal 8278 may include a connector via which the electronic apparatus 8201 may be physically connected with another electronic apparatus (e.g., the electronic apparatus 8202, etc.). The connecting terminal 8278 may include a HDMI connector, a USB connector, a SD card connector, and/or an audio connector (e.g., a headphone connector, etc.).

The haptic module 8279 may convert an electrical signal into a mechanical stimulus (e.g., a vibration, a movement, etc.) or electrical stimulus which may be recognized by a user via his tactile sensation or kinesthetic sensation. The haptic module 8279 may include a motor, a piezoelectric element, and/or an electric stimulator.

The camera module 8280 may capture a still image or moving images. The camera module 8280 may include a lens assembly including one or more lenses, image sensors, image signal processors, and/or flashes. The lens assembly included in the camera module 8280 may collect light emitted from the subject, which is the target of image capturing.

The power management module 8288 may manage the power supplied to the electronic apparatus 8201. The power management module 8388 may be implemented as part of the power management integrated circuit (PMIC).

The battery 8289 may supply power to the components of the electronic apparatus 8201. The battery 8289 may include a primary cell which is not rechargeable, a secondary cell which is rechargeable, and/or a fuel cell.

The communication module 8290 may support establishing a direct (e.g., wired) communication channel and/or a wireless communication channel between the electronic apparatus 8201 and another electronic apparatus (e.g., the electronic apparatus 8202, the electronic apparatus 8204, the server 8208, etc.) and performing communication via the established communication channel. The communication module 8290 may include one or more communication processors that are operable independently from the processor 8220 (e.g., the application processor, etc.) and supports a direct communication and/or a wireless communication. The communication module 8290 may include a wireless communication module 8292 (e.g., a cellular communication module, a short-range wireless communication module, a global navigation satellite system (GNSS) communication module, etc.) and/or a wired communication module 8294 (e.g., a local area network (LAN) communication module, a power line communication module, etc.). A corresponding one of these communication modules may communicate with another electronic apparatus via a first network 8298 (e.g., a short-range communication network, such as Bluetooth™, wireless-fidelity (Wi-Fi) direct, infrared data association (IrDA), etc.) or a second network 8299 (e.g., a long-range communication network, such as a cellular network, the Internet, or a computer network (e.g., local area network (LAN), wide area network (WAN), etc.). These various types of communication modules may be implemented as a single component (e.g., a single chip, etc.), or may be implemented as multi components (e.g., multi chips, etc.) separate from each other. The wireless communication module 8292 may identify and authenticate the electronic apparatus 301 in a communication network, such as the first network 8298 and/or the second network 8299, using subscriber information (e.g., international mobile subscriber identity (IMSI), etc.) stored in the subscriber identification module 8296.

The antenna module 8297 may transmit or receive a signal and/or power to or from the outside (e.g., another electronic apparatus, etc.). The antenna may include a radiating element including a conductive pattern formed on a substrate (e.g., a printed circuit board (PCB), etc.). The antenna module 8297 may include one or a plurality of antennas. If a plurality of antennas are included, an antenna appropriate for a communication scheme used in a communication network, such as the first network 8298 and/or the second network 8299, may be selected by the communication module 8290, from the plurality of antennas. Signals and/or power may be transmitted or received between the communication module 8290 and another electronic apparatus via the selected antenna. Another component (e.g., a radio frequency integrated circuit (RFIC), etc.) other than the antenna may be included as part of the antenna module 8297.

Some of the components are connected to each other through communication methods between peripheral devices (e.g., buses, general purpose input and output (GPIO), serial peripheral interface (SPI), mobile industry processor interface (MIPI), etc.) and may interchange signals (e.g., command, data, etc.) with each other.

The command or data may be transmitted or received between the electronic apparatus 8201 and the external electronic apparatus 8204 through the server 8208 connected to the second network 8299. The other electronic apparatuses 8202 and 8204 may be the same as or different from the electronic apparatus 201. All or some of operations executed in the electronic apparatus 8201 may be executed in one or more of the other electronic apparatuses 8202, 8204, and 8208. For example, when the electronic apparatus 8201 needs to perform a function or service, instead of executing a function or service itself, the electronic apparatus 8201 may request one or more other electronic apparatuses to perform part of or the entire function or service. One or more other electronic apparatuses that received the request may execute an additional function or service related to the request and may transmit a result of the execution to the electronic apparatus 8201. To this end, cloud computing, distributed computing, and/or client-server computing technology may be used.

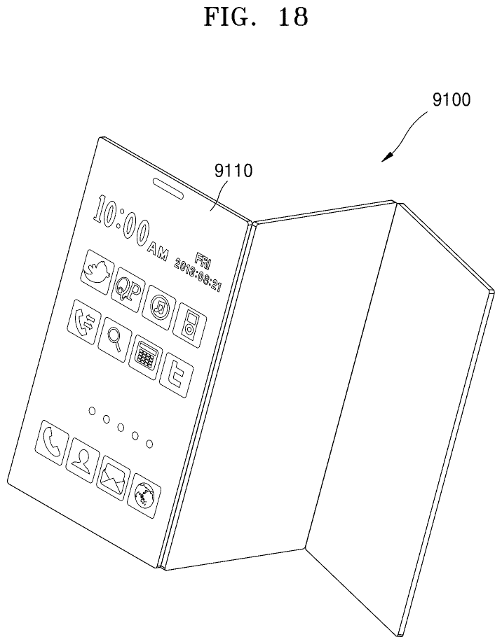

FIG. 18 illustrates an example in which an electronic apparatus according to an example embodiment is applied to a mobile apparatus 9100. The mobile apparatus 9100 may include a display apparatus 9103, and the display apparatus 9103 may include display apparatuses according to an example embodiment. The display apparatus 9103 may include a foldable structure, for example, a multiple foldable structure.

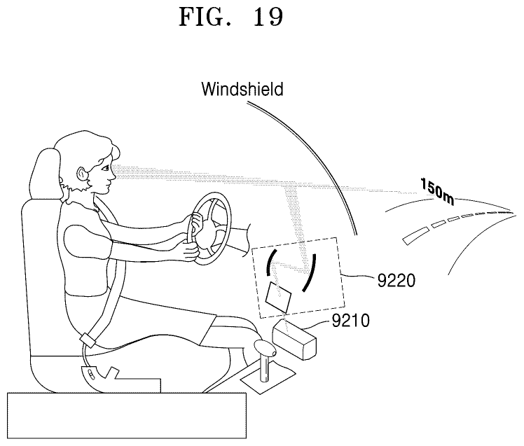

FIG. 19 illustrates an example of a display apparatus applied to a vehicle, according to an example embodiment. The display apparatus may be a head-up display apparatus 9200 for a vehicle, and may include a display 9210 disposed in an area of the vehicle, and a light path changing unit 9220 that converts a light path such that an image generated by the display 9210 is viewable to a driver.

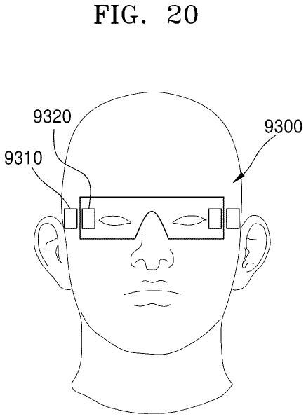

FIG. 20 illustrates an example in which a display apparatus according to an example embodiment is applied to augmented reality glasses or virtual reality glasses. The augmented reality glasses 9300 may include a projection system 9310 forming an image and an element 9320 guiding the image from the projection system 9310 to the eyes of a user. The projection system 9310 may include a display apparatus according to an example embodiment.

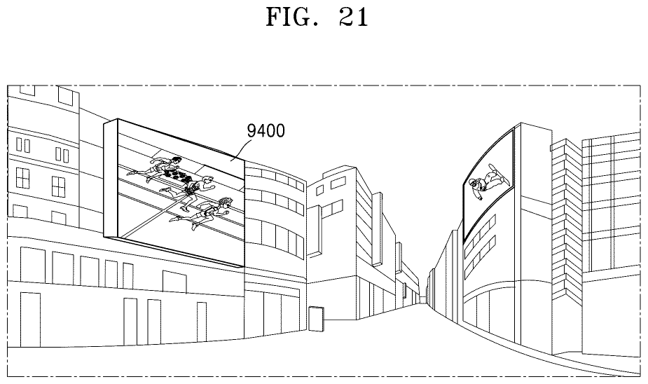

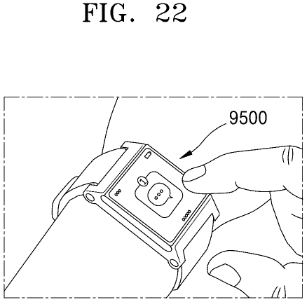

FIG. 21 illustrates an example of a display apparatus applied to a large signage, according to an example embodiment. The signage 9400 may be used for outdoor advertising using a digital information display and may control contents of advertisements through a communication network. The signage 9400 may be implemented, for example, through the electronic apparatus described with reference to FIG. 18.

FIG. 19 illustrates an example of the display apparatus applied to a wearable display 9500, according to an example embodiment. The wearable display 9500 may include a display apparatus according to an example embodiment and may be implemented through the electronic apparatus described with reference to FIG. 17.

The display apparatus according to an example embodiment may also be applied to various products such as a rollable TV, a stretchable display, and the like.

The semiconductor light-emitting device and the display apparatus including the semiconductor light-emitting device may be configured to emit light of a red wavelength and may include a passivation layer including AlON, thereby increasing the PL intensity. As the semiconductor light-emitting device emitting light of a red wavelength is miniaturized, the luminescence efficiency is decreased. However, the passivation layer may be provided to enhance the luminescence efficiency. The disclosed manufacturing method of the semiconductor light-emitting device may provide a method of depositing the AlON passivation layer on the light-emitting stack structure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor light-emitting device, comprising:
a light-emitting stack structure comprising a first semiconductor layer, an active layer disposed on the first semiconductor layer, and a second semiconductor layer disposed on the active layer; and
a first passivation layer disposed on a side surface of the light-emitting stack structure,
wherein the light-emitting stack structure is configured to emit light having a light-emitting peak wavelength in a range of about 610 nm to about 650 nm, and
wherein the first passivation layer comprises aluminum oxynitride (AlON).

2. The semiconductor light-emitting device of claim 1, wherein a composition ratio of nitrogen in AlON of the first passivation layer is in a range of about 1 at % to about 10 at %.

3. The semiconductor light-emitting device of claim 1, wherein a thickness of the first passivation layer is in a range of about 1 nm to about 50 nm.

4. The semiconductor light-emitting device of claim 1, further comprising a second passivation layer disposed on the first passivation layer.

5. The semiconductor light-emitting device of claim 4, wherein the second passivation layer comprises at least one of SiO₂, SiN, SiCN, SiOC, SiON, SiOCN, HfOₓ, AlOₓ, ZrOₓ, AlN, AlOₓN_{y}, Ta₂O₃, or Ta₂O₅.

6. The semiconductor light-emitting device of claim 5, wherein the second passivation layer is stacked in one to five layers.

7. The semiconductor light-emitting device of claim 4, wherein the second passivation layer comprises an amorphous material.

8. The semiconductor light-emitting device of claim 4, wherein the second passivation layer has a thickness of about 1 nm to about 15 nm.

9. The semiconductor light-emitting device of claim 1, further comprising a SiO₂ passivation layer and a Al₂O₃ passivation layer included in the first passivation layer.

10. The semiconductor light-emitting device of claim 1, wherein the semiconductor light-emitting device has a diameter in a range of about 0.5 μm to about 2 μm.

11. The semiconductor light-emitting device of claim 1, wherein the semiconductor light-emitting device has a height in a range of about 2 μm to about 7 μm.

12. A display apparatus, comprising:
a plurality of pixel electrodes;
a common electrode corresponding to the plurality of pixel electrodes;
a plurality of semiconductor light-emitting devices connected between each of the plurality of pixel electrodes and the common electrode; and
a driving circuit layer configured to drive the plurality of semiconductor light-emitting devices,
wherein each semiconductor light-emitting device of the plurality of semiconductor light-emitting devices comprises:
a light-emitting stack structure comprising a first semiconductor layer, an active layer disposed on the first semiconductor layer, and a second semiconductor layer disposed on the active layer; and
a first passivation layer disposed on a side surface of the light-emitting stack structure, wherein the light-emitting stack structure is configured to emit light having a light-emitting peak wavelength in a range of about 610 nm to about 650 nm, and
wherein the first passivation layer comprises aluminum oxynitride (AlON).

13. The display apparatus of claim 12, wherein a composition ratio of nitrogen in AlON of the first passivation layer is in a range of about 1 at % to about 10 at %.

14. The display apparatus of claim 12, wherein a thickness of the first passivation layer is in a range of about 1 nm to about 50 nm.

15. The display apparatus of claim 12, wherein each semiconductor light-emitting device further comprises:
a second passivation layer disposed on the first passivation layer, and
wherein the second passivation layer comprises at least one of SiO₂, SiN, SiCN, SiOC, SiON, SiOCN, HfOₓ, AlOₓ, ZrOₓ, AlN, AlOₓN_{y}, Ta₂O₃, or Ta₂O₅.

16. A method of manufacturing a semiconductor light-emitting device, the method comprising:
forming a first semiconductor layer on a substrate;
forming an active layer on the first semiconductor layer;
forming a second semiconductor layer on the active layer;
forming a plurality of light-emitting stack structures by etching the first semiconductor layer, the active layer, and the second semiconductor layer; and
depositing a first passivation layer on the plurality of light-emitting stack structures,
wherein the plurality of light-emitting stack structures are formed to emit light having a peak wavelength in a range of about 610 nm to about 650 nm, and
wherein the depositing of the first passivation layer comprises selectively repeating, a plurality of times, a process of AlN deposition and Al₂O₃ deposition and a plasma process.

17. The method of claim 16, wherein the process of the AlN deposition and the Al₂O₃ deposition comprises performing the AlN deposition two consecutive times and performing the Al₂O₃ deposition two consecutive times.

18. The method of claim 16, wherein, in the process of the AlN deposition and the Al₂O₃ deposition, the AlN deposition is performed earlier than the Al₂O₃ deposition.

19. The method of claim 16, wherein the depositing the first passivation layer comprises depositing a passivation layer material in which a composition ratio of nitrogen in aluminum oxynitride (AlON) is in a range of about 1 at % to about 10 at %.

20. The method of claim 16, wherein the depositing the first passivation layer is performed such that a thickness of the first passivation layer is in a range of about 1 nm to about 50 nm.
